(19) United States
(12) Patent Application Publication
(10) Pub. No.: US 2013/0061901 A1
(43) Pub. Date: Mar. 14, 2013

(54) THERMOELECTRIC CONVERTING MODULE AND MANUFACTURING METHOD THEREOF

(71) Applicants: Tomotake TOHEI, Yokohama (JP); Shinichi Fujiwara, Yokohama (JP); Takahiro Jinushi, Matsudo (JP); Zenzo Ishijima, Matsudo (JP)

(72) Inventors: Tomotake TOHEI, Yokohama (JP); Shinichi Fujiwara, Yokohama (JP); Takahiro Jinushi, Matsudo (JP); Zenzo Ishijima, Matsudo (JP)

(21) Appl. No.: 13/606,418

(22) Filed: Sep. 7, 2012

(30) Foreign Application Priority Data
Sep. 8, 2011 (JP) 2011-196426
Sep. 6, 2012 (JP) 2012-195703

(51) Int. Cl. H01L 35/32; H01L 35/14; H01L 35/34

(52) U.S. Cl. 136/205; 438/54; 136/201; 257/E21.04

(57) ABSTRACT

Provided is a high temperature thermoelectric converting module including a plurality of p type thermoelectric elements; a plurality of n type thermoelectric elements; a plurality of electrodes; and a lead line. The plurality of p type thermoelectric elements, the plurality of n type thermoelectric elements, and the plurality of electrodes are electrically serially connected to each other, a pair of connecting lines that connects the lead line to one of the plurality of electrodes to output to the outside is further included, at least one electrode which is disposed at the high temperature side and the plurality of p type and n type thermoelectric elements are bonded with an intermediate layer therebetween. The plurality of p type and n type thermoelectric elements contain silicon as a component and the intermediate layer is formed as a layer containing aluminum and silicon and components other than silicon of the thermoelectric elements.

### CLAIM OF PRIORITY

The present application claims priority from Japanese Patent Application JP 2011-196426 filed on Sep. 8, 2011, the content of which is hereby incorporated by reference into this application.

### BACKGROUND

The present invention relates to a thermoelectric converting module that improves a bonding reliability of a thermoelectric converting element and an electrode and a manufacturing method thereof.

A thermoelectric converting module that converts a thermal energy into electric energy has an advantage in that no maintenance is required because no driving unit is provided, no vibration is generated, and simple configuration is provided. In the meantime, the thermoelectric converting module has low energy converting efficiency so that it has been used in a limited location such as the space. In recent years, due to environmental concerns, a thermoelectric converting module attracts attention as a method of collecting the thermal energy which has been uselessly wasted as waste heat and the thermoelectric converting module is expected to be used for a vehicle, an industrial furnace, or a garbage incinerator. Thus, reduction in costs for the thermoelectric converting module and improvement in the durability thereof are required.

However, currently, a practically used thermoelectric converting module, as described in Japanese Patent Application Laid-Open Publication No. 9-293906, is mainly bismuth tellurium based and the operating temperature thereof is limited to low temperature in the range of 300° C. or lower. Therefore, if the above-mentioned application of the thermoelectric converting module to the industrial furnace or the vehicle is considered, a silicon germanium based, magnesium silicide based, or a manganese silicide based thermoelectric converting module which operates at a higher temperature than a bismuth tellurium based thermoelectric converting module is required.

In the related art, the bismuth tellurium based thermoelectric converting element and the electrode are generally bonded by a soft brazing filler material such as a solder. However, if the high temperature thermoelectric converting material is bonded using the soft brazing filler material, the soft brazing filler material is melted and flowed under the usage environment of the thermoelectric converting module, which may lower a bonding reliability of the thermoelectric converting element and the electrode. Further, when the soft brazing filler material is used, there is an upper temperature limit of the thermoelectric converting module.

To the contrary, in Japanese Patent Application Laid-Open Publication No. 9-293906, it is described that between a part of bismuth telluride based or lead telluride based P type or N type conductive semiconductor and a copper electrode, an interposing layer which is one of a group consisting of Al, Mg, and Ti or an alloy thereof is provided and the a hard brazing filler material having high thermal resistance is used to increase the thermal resistance of the thermoelectric converting module. Further, Cu of the electrode material is bonded so as to prevent Cu from being diffused onto the semiconductor.

In the meantime, in Japanese Patent Application Laid-Open Publication No. 2005-317834, in order to address problems caused by using the soft brazing filler material, a thermoelectric converting module in which an end portion of the thermoelectric converting element are bonded with an electrode material via an interposing layer formed of silver by a hard brazing filler material is described.

Further, in Japanese Patent Application Laid-Open Publication No. 2003-304006, it is described that between a P type cobalt antimony based thermoelectric converting element and an electrode member and between an n type cobalt antimony based thermoelectric converting element and an electrode member, a thin film layer which mainly includes aluminum is formed to bond them.

In addition, in Japanese Patent Application Laid-Open Publication No. 2006-49736, a configuration in that titan or a titan alloy layer, or titan or a titan alloy layer and aluminum or an aluminum alloy layer are interposed as an intermediate layer between a P type thermoelectric element and an N type thermoelectric element which are formed of a magnesium silicide (Mg—Si) based alloy and an electrode to be connected is described.

### SUMMARY

When the thermoelectric converting element and the electrode are bonded as described above, the following problems may be caused.

### (1) Solder Bonding

In case of a lead free solder which is commonly used presently, a melting point of the solder is approximately 220° C. Further, even in a high temperature lead free solder, the melting point is 400° C. or lower. Further, the high temperature lead free solder has various problems such as brittle solder material, low heat conduction, bad wettability, and high costs.

### (2) Pressurization, Compressed Bonding

Since the bonding type of the thermoelectric element and the electrode is a contact type, a converting efficiency of the thermoelectric converting module may be deteriorated due to a contact thermal resistance at a contacting interface. Further, if a pressurizing force is raised in order to reduce the contact thermal resistance, a thermal stress is loaded in addition to the pressurizing force under the usage environment of the thermoelectric converting module, which may deteriorate the reliability of the thermoelectric converting module.

### (3) Bonding by a Hard Brazing Filler Material

The hard brazing filler material has the melting point of approximately 600 to 800° C., which is higher than that of the solder material and is applicable to a high temperature environment as a bonding material. The hard brazing filler material includes a silver solder which includes silver as a main component or a gold solder which includes gold as a main component. Generally, a solder material which is used as a bonding material of a high temperature module has a bonding strength of 5 to 25 MPa. Therefore, the bonding strength is low and the bonded portion is significantly deteriorated by oxidation under a high temperature environment under the atmosphere. Further, the bonding reliability is lowered.

### (4) Bonding With an Interposed Intermediate Layer Interposed

As described in Japanese Patent Application Publication Nos. 2003-304006 and 2006-49736, it is disclosed that the thermoelectric element and the electrode are connected with aluminum or an aluminum alloy interposed between the thermoelectric element and the electrode. However, according to a method described in Japanese Patent Application Laid-Open Publication No. 2003-304006, at the time of bonding, a pressure of 300 kg/cm² or higher and 700 kg/cm² or lower is applied while being heated at a temperature of 525° C. or higher and 575° C. or lower, which may cause damage to the thermoelectric element to deteriorate the bonding reliability between the thermoelectric element and the electrode. Further, according to a method described in Japanese Patent Application Laid-Open Publication No. 2006-49736, at the time of bonding, a pressure of several tens MPa is applied while being heated at 600 to 700° C., which may cause damage to the thermoelectric element to deteriorate the bonding reliability between the thermoelectric element and the electrode.

Therefore, the present invention has been made in an effort to provide a thermoelectric converting module which has a high bonding strength between the thermoelectric element and the electrode and suppresses the deterioration of the bonding reliability between the thermoelectric electrode and the electrode even under the high temperature environment in a configuration of bonding a high temperature thermoelectric element and an electrode.

In order to address the above object, according to an embodiment of the present invention, there is provided a thermoelectric converting module including: a plurality of p type thermoelectric elements; a plurality of n type thermoelectric elements; a plurality of electrodes; and a lead line. The plurality of p type thermoelectric elements, the plurality of n type thermoelectric elements, and the plurality of electrodes are electrically serially connected to each other, a pair of connecting lines that connects the lead line to one of the plurality of electrodes to output to the outside is further included, at least one electrode which is disposed at the high temperature side and the plurality of p type thermoelectric elements and the plurality of n type thermoelectric elements are bonded with an intermediate layer therebetween. The plurality of p type thermoelectric elements and the plurality of n type thermoelectric elements contain silicon as a component and the intermediate layer is formed as a layer containing aluminum and silicon and components other than silicon of the thermoelectric elements.

According to another embodiment of the present invention, there is provided a thermoelectric converting module including: a plurality of p type thermoelectric elements; a plurality of n type thermoelectric elements; a plurality of electrodes; and a lead line. The plurality of p type thermoelectric elements, the plurality of n type thermoelectric elements, and the plurality of electrodes are electrically serially connected to each other, a pair of connecting lines that connects the lead line to one of the plurality of electrodes to output to the outside is further included, at least one electrode which is disposed at the high temperature side and the plurality of p type thermoelectric elements and the plurality of n type thermoelectric elements are bonded with an intermediate layer therebetween. The plurality of p type thermoelectric elements and the plurality of n type thermoelectric elements contain silicon as a component, the plurality of p type thermoelectric elements and the plurality of n type thermoelectric elements are bonded to the intermediate layer with a barrier layer formed of tungsten, titanium, nickel, palladium, molybdenum or an alloy including any one of the above metals interposed therebetween, and the intermediate layer is formed as an aluminum layer or a layer containing aluminum and a component generating a liquid phase with aluminum.

Specifically, when a silicon germanium based thermoelectric element is used for at least one of the p type thermoelectric elements and the n type thermoelectric elements, the intermediate layer includes aluminum and an alloy of silicon and germanium. When a magnesium silicide based thermoelectric element is used for at least one of the p type thermoelectric elements and the n type thermoelectric elements, the intermediate layer includes aluminum and an alloy of silicon and magnesium. Further, when a manganese silicide based thermoelectric element is used for at least one of the p type thermoelectric elements and the n type thermoelectric elements, the intermediate layer includes aluminum and an alloy of silicon and manganese.

In order to address the above object, according to an embodiment of the present invention, there is provided a method of manufacturing a thermoelectric converting module, including: providing p type thermoelectric elements and n type thermoelectric elements at a side of one surface of an electrode plate with an intermediate layer forming member interposed therebetween; heating the p type thermoelectric elements and the n type thermoelectric elements while compressing the p type thermoelectric elements and the n type thermoelectric element at the surface of the electrode plate to melt the intermediate layer forming member; and cooling the melted intermediate layer forming member to bond between the p type thermoelectric elements and the electrode plate and between the n type thermoelectric elements and the electrode plate. The p type thermoelectric elements and the n type thermoelectric elements contain silicon as a component, the intermediate layer forming member is formed of aluminum or an aluminum alloy containing a component of the thermoelectric elements containing the silicon as a component, and the heating is performed at a temperature where the intermediate layer forming member is melted to bond between the p type thermoelectric elements and the electrode plate and between the n type thermoelectric elements and the electrode.

According to another embodiment of the present invention, there is provided a method of manufacturing a thermoelectric converting module, including: providing p type thermoelectric elements and n type thermoelectric elements at a side of one surface of an electrode plate with an intermediate layer forming member interposed therebetween; heating the p type thermoelectric elements and the n type thermoelectric elements while compressing the p type thermoelectric elements and the n type thermoelectric elements at a side of one surface of the electrode plate to melt the intermediate layer forming member; and cooling the melted intermediate layer forming member to bond between the p type thermoelectric elements and the electrode plate and between the n type thermoelectric elements and the electrode plate. The intermediate layer forming member is formed of aluminum or an aluminum alloy containing aluminum and a liquid phase generating component, a diffusion barrier layer is formed on end faces of the p type thermoelectric elements and the n type thermoelectric elements, the p type thermoelectric elements and the n type thermoelectric elements are provided so as to face the diffusion barrier layer and the intermediate layer forming member, and the heating is performed at a temperature where the intermediate layer forming member is melted to bond between the p type thermoelectric elements and the electrode plate and between the n type thermoelectric elements and the electrode plate.

In the above-mentioned method of manufacturing a thermoelectric converting module, as the intermediate layer forming member, at least one of an aluminum foil, an aluminum alloy foil containing at least the silicon in aluminum as a component, an aluminum powder, and an aluminum alloy powder containing at least the silicon in aluminum as a component is used and the intermediate layer forming member is interposed between the thermoelectric element containing silicon as a component and the electrode.

Further, as the intermediate layer forming member, a metal layer formed of at least one of aluminum and an aluminum alloy containing at least the silicon in the aluminum as a component is formed on at least one of an end portion of the thermoelectric elements containing the silicon as a component which is bonded to the electrode and a portion of the electrode which comes in contact with the thermoelectric element containing the silicon as a component to be the intermediate layer forming member.

According to the embodiment of the present invention, high strength bonding may be ensured by a metal bonding and the bonding reliability may be secured under a high temperature environment.

Accordingly, in the thermoelectric converting module which is used under a high temperature environment, even though a thermal stress is loaded to a bonded portion by a difference in coefficients of linear expansion between individual members, a bonded portion having an excellent thermal resistant fatigability may be formed. Further, when the thermoelectric converting module is used under the high temperature environment, the lowering of the strength of the bonded portion is suppressed.

These features and advantages of the invention will be apparent from the following more particular description of preferred embodiments of the invention, as illustrated in the accompanying drawings.

### BRIEF DESCRIPTION OF THE DRAWINGS

FIG. 1 is a perspective diagram illustrating a schematic configuration of a thermoelectric converting module of an embodiment of the present invention;

FIG. 2 is a front view of a single body of a thermoelectric converting module according to a first embodiment of the present invention;

FIG. 3A is a front view of a thermoelectric element and an electrode schematically illustrating a status where a metal foil is disposed between the thermoelectric element and the electrode in a manufacturing method of the thermoelectric converting module according to the first embodiment of the present invention;

FIG. 3B is a front view of a thermoelectric element and an electrode schematically illustrating a status where the thermoelectric element and the electrode are compressed while being heated with a metal foil interposed therebetween in a manufacturing method of the thermoelectric converting module according to the first embodiment of the present invention;

FIG. 3C is a front view of a thermoelectric element and an electrode schematically illustrating a status where the thermoelectric element and the electrode are compressed while being heated and a metal foil interposed therebetween is melted, and then the thermoelectric element and the electrode are uncompressed and cooled to form an alloy to be bonded in a manufacturing method of the thermoelectric converting module according to the first embodiment of the present invention;

FIG. 4A is an SEM image of a cross-section of a bonded portion according to the first embodiment of the present invention;

FIG. 4B is a view illustrating a distribution status of various elements by an EDX of a cross-section of the bonded portion according to the first embodiment of the present invention;

FIG. 5 is a schematic view of a cross-section of the bonded portion according to the first embodiment of the present invention;

FIG. 6A is a front view of the thermoelectric element and the electrode schematically illustrating a status where the thermoelectric element and the electrode are overheated and pressurized using a metal layer disposed at the side of the thermoelectric element instead of the metal foil to be bonded in a modification example of the first embodiment of the present invention;

FIG. 6B is a front view of the thermoelectric element and the electrode schematically illustrating a status where the thermoelectric element and the electrode are overheated and pressurized using a metal layer disposed at the side of the electrode instead of the metal foil to be bonded in a modification example of the first embodiment of the present invention;

FIG. 7 is a front view of a single body of a thermoelectric converting module according to a second embodiment of the present invention;

FIG. 8A is a front view of a thermoelectric element and an electrode schematically illustrating a status where a metal foil is disposed between the thermoelectric element and the electrode in a manufacturing method of the thermoelectric converting module according to the second embodiment of the present invention;

FIG. 8B is a front view of a thermoelectric element and an electrode schematically illustrating a status where the thermoelectric element and the electrode are compressed while being heated with a metal foil interposed therebetween in a manufacturing method of the thermoelectric converting module according to the second embodiment of the present invention;

FIG. 8C is a front view of a thermoelectric element and an electrode schematically illustrating a status where the thermoelectric element and the electrode are compressed while being heated and a metal foil interposed therebetween is melted, and then the thermoelectric element and the electrode are uncompressed and cooled to form an alloy to be bonded in a manufacturing method of the thermoelectric converting module according to the second embodiment of the present invention; and

FIG. 9 is a graph illustrating a relationship between a time when holding at a high temperature and a shear strength as a result of a bonding strength experiment according to the first embodiment of the present invention.

### DESCRIPTION OF THE PREFERRED EMBODIMENTS

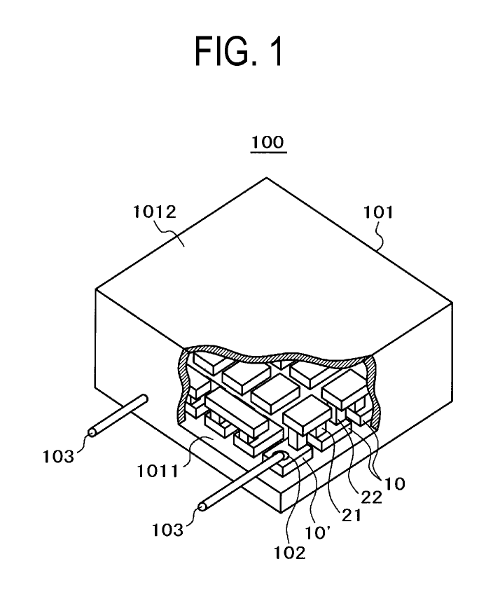

Hereinafter, embodiments of the present invention will be described with reference to the accompanying drawings. FIG. 1 illustrates an example of an exterior appearance of a thermoelectric converting module 100 according to an embodiment of the present invention. The thermoelectric converting module 100 is configured such that electrodes 10 and n type thermoelectric elements 21 and p type thermoelectric elements 22 are alternately and two dimensionally disposed to be parallel in a case 101 that covers the outside and the n type thermoelectric elements 21 and the p type thermoelectric elements 22 are electrically serially connected by the plurality of electrodes 10. Each of the plurality of electrodes 10 is closely attached onto an inner wall face 1011 of the case 101. Among outer wall faces of the case 101, an upper surface 1012 comes in contact with a heating member and a lower surface 1013 is cooled by a cooling device which is not illustrated. A terminal 102 is formed in electrodes 10′ which are disposed at end portions of the two-dimensionally arranged electrodes 10 in the case 101 and a lead line which extends to the outside of the case 101 is connected to the terminal 102 to output the power generated by the thermoelectric converting module 100 to the outside.

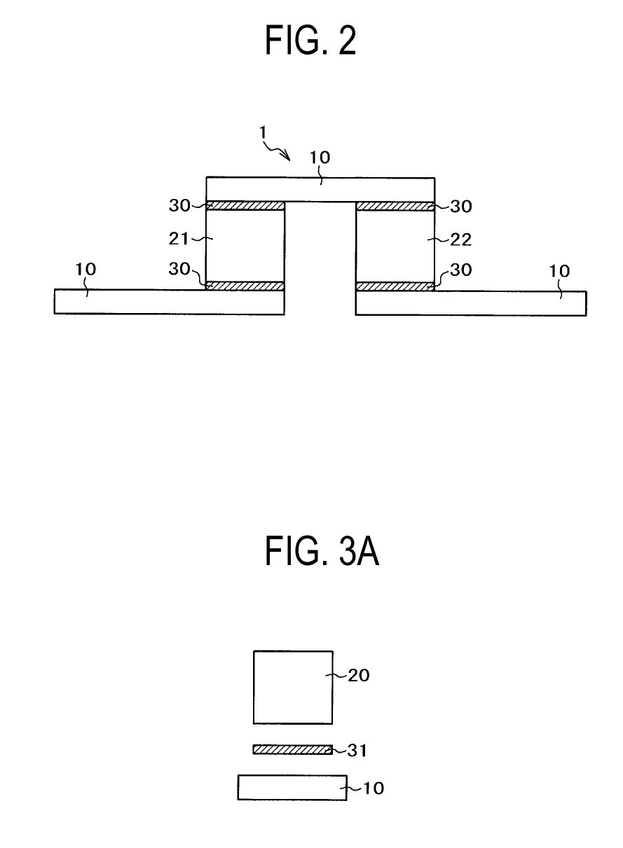

A single body of the thermoelectric converting module configured by the electrode 10, the n type thermoelectric element 21, and the p type thermoelectric element 22 illustrated in FIG. 1 will be described and the thermoelectric converting module according to the first embodiment of the present invention will be described with reference to FIG. 2. FIG. 2 is a schematic cross-sectional view illustrating an example of a combination of the electrode 10, the n type thermoelectric element 21, and the p type thermoelectric element 22 that configure the single body of the thermoelectric converting module. In FIG. 2, reference numeral 1 denotes the single body of a thermoelectric converting module, reference numeral 10 denotes the electrode, reference numeral 21 denotes the n type thermoelectric element, reference numeral 22 denotes the p type thermoelectric element, and reference numeral 30 denotes an intermediate layer.

The n type thermoelectric element 21 is a silicon germanium-thermoelectric element obtained by sintering silicon germanium powder containing an impurity such as phosphorus or antimony of 1% or less which defines characteristics of an n type semiconductor by a pulse discharging method or a hot press method. The p type thermoelectric element 22 is a silicon-germanium thermoelectric element obtained by sintering silicon germanium powder containing an impurity such as boron, aluminum or a gallium of 1% or less which defines characteristics of a p type semiconductor by the pulse discharging method or the hot press method. Further, the n type thermoelectric element 21 and the p type thermoelectric element 22 (hereinafter, collectively referred to as a thermoelectric element 20) may be a magnesium silicide thermoelectric element obtained by sintering magnesium silicide powder by the pulse discharging method or the hot press method or a manganese silicide thermoelectric element obtained by sintering manganese silicide powder by the pulse discharging method or the hot press method. Hereinafter, a silicon-germanium thermoelectric element will be described as an example of the thermoelectric element 20.

The electrode 10 may be configured a single body or plural layers consisting of molybdenum, copper, tungsten, titanium, nickel or an alloy of molybdenum, copper, tungsten, titanium, or nickel. Hereinafter, a molybdenum electrode may be described as an example of the electrode 10.

The intermediate layer 30 is formed as a layer including aluminum, silicon, and germanium because the thermoelectric element 20 has silicon and germanium as main components.

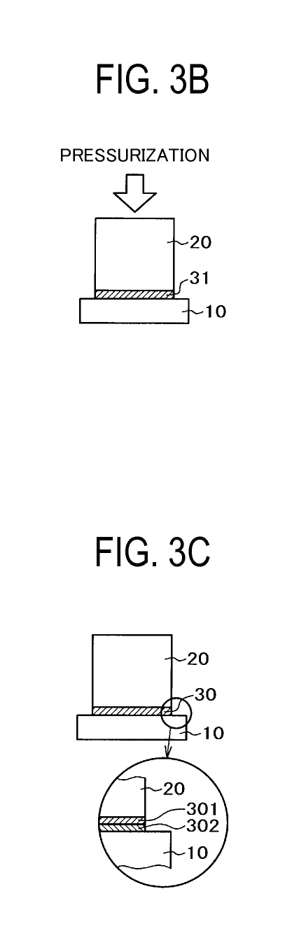

FIGS. 3A to 3C are schematic explanatory diagrams illustrating a manufacturing method of the thermoelectric converting module single body 1 according to the first embodiment of the present invention shown in FIG. 2. Referring to FIGS. 3A to 3C, reference numeral 10 denotes an electrode, reference numeral 20 denotes a thermoelectric element, reference numeral 31 denotes a metal foil, and reference numeral 30 denotes an intermediate layer generated as a result of the bonding. Here, the electrode 10 is a metal having molybdenum as a main component and the thermoelectric element 20 is a semiconductor having silicon-germanium as a main component.

The metal foil 31 may be an aluminum foil, an aluminum alloy foil containing silicon and germanium, an aluminum powder or an aluminum alloy powder containing silicon and germanium, and the thickness of the metal foil 31 is several μm to several tens μm. Hereinafter, an aluminum foil will be described as an example of the metal foil 31.

A plurality of thermoelectric converting module single bodies 1 is simultaneously formed. A manufacturing method thereof is as follows: first, a plurality of electrodes 10 (hereinafter, referred to as a molybdenum electrode 10) having molybdenum as a main component is mounted in an electrode alignment jig (not illustrated) which may suck or adhere the electrodes and a plurality of thermoelectric elements 20 which is a silicon-germanium thermoelectric element is adhered onto an element alignment jig (not illustrated) which may suck or adhere the thermoelectric element 20. As illustrated in FIG. 3A, an aluminum foil which is the metal foil 31 is provided as an intermediate layer forming member between the thermoelectric element 20 which is a silicon-germanium thermoelectric element and the molybdenum electrode 10. Thereafter, as schematically illustrated in FIG. 3B, the thermoelectric converting module single body is pressurized from the upper part of the silicon-germanium thermoelectric element (thermoelectric element 20) at 0.12 kPa or higher while being heated at a temperature where the intermediate layer forming member is melted. The bonding atmosphere may be a nonoxidization atmosphere and specifically, a vacuum atmosphere, a nitrogen atmosphere, or a nitrogen and hydrogen mixture atmosphere. Thereafter, by cooling up to a room temperature, an intermediate layer 30 is formed between the silicon-germanium thermoelectric element and the molybdenum electrode as illustrated in FIG. 3C. Accordingly, the intermediate layer 30 is formed as a layer containing aluminum, silicon, and germanium.

In the intermediate layer 30, at least one or plural alloy layers containing aluminum, silicon, and germanium generated by dissolving silicon-germanium that forms the thermoelectric element 20 in aluminum which is a component of the metal foil 31 may be formed. In case of the plural alloy layers, for example, the intermediate layer 30 has a layered structure including an alloy layer 301 including aluminum, silicon, and germanium and an alloy layer 302 of silicon and germanium including aluminum of 10 mass % or less.

The plurality of thermoelectric converting module 1 formed as described above is mounted inside the case 101 of FIG. 1 and the lead line 103 fixed to the electrode 10′ is led out to the outside of the case 101 and the case 101 is sealed to complete the thermoelectric converting module 100. Further, some thermoelectric converting modules are not accommodated in the case 101. Therefore, in case of such a thermoelectric converting module, the module may be not accommodated in the casing.

Here, the reason why the pressurizing force is set 0.12 kPa or higher is that, the thermoelectric element 20 is prevented from being slanted at the time of bonding, the adhesiveness between the thermoelectric element 20 and the molybdenum electrode 10 is increased, an oxidized film formed on a melted aluminum surface at the time of bonding is destroyed and a newly generated aluminum surface is brought into contact with a surface of the thermoelectric element and a surface of the molybdenum electrode to obtain good bonding. Even though the upper limit of the pressurizing force is not specifically defined, the pressurizing force needs to be set not to destroy the element. Accordingly, the pressurizing force may be set to be less than a crushing strength of the element. Specifically, the pressurizing force may be 1,000 MPa or less. In the present invention, as described in Japanese Patent Application Laid-Open Publication Nos. 2003-304006 and 2006-49736, without applying a pressure of 300 kg/cm² or higher and 700 kg/cm² or lower or a pressure of several tens MPa at the time of bonding, a pressure of only several MPa should be sufficient.

Further, in a heating and pressurizing process illustrated in FIG. 3B, if the temperature is 580° C. which is a bonding temperature or higher, silicon is diffused from the thermoelectric element 20 that has silicon and germanium as main components into aluminum of the metal foil 31. Accordingly, aluminum of the metal foil 31 is melted at 577° C. which is a eutectic temperature of the aluminum-silicon alloy. By melting aluminum of the metal foil 31, silicon-germanium which is the main component of the thermoelectric element 20 and aluminum of the metal foil 31 are in a coexistence state of a solid phase and liquid phase and germanium is diffused to form a silicon and aluminum liquid phase including germanium. After forming the silicon and aluminum liquid phase including germanium, aluminum is diffused from the liquid phase into silicon-germanium that forms the thermoelectric element 20 to form an alloy layer 301. Along with the composition change of the liquid phase, an alloy layer 302 which has silicon and aluminum as main components is formed.

In other words, the formation of the intermediate layer 30 is a bonding type that uses a liquid phase diffusion bonding method. Aluminum which has a lower melting point than silicon and germanium is diffused from the liquid phase including silicon, germanium, and aluminum into the silicon-germanium that forms the thermoelectric element 20 to reduce the concentration of aluminum in the liquid phase and raise the melting point of the liquid phase to be isothermally solidified.

Therefore, after bonding, as illustrated in FIG. 3C, between the thermoelectric element 20 that has silicon-germanium as a main component and the molybdenum electrode 10, a layer containing aluminum, silicon, and germanium formed by diffusing silicon-germanium which is the main component of the thermoelectric element 20 and aluminum which is contained in the metal foil 31 is formed as the intermediate layer 30. The intermediate layer 30 has a high bonding strength, excellent oxidation resistance and corrosion resistance for containing silicon, germanium, and aluminum and the deterioration of the bonded portion may hardly occur under a high temperature environment under the atmosphere.

Further, by adjusting a bonding temperature, a bonding time, and a pressure, a silicon and aluminum liquid phase including germanium is generated before reaching 660° C. which is a melting point of aluminum which is the component of the metal foil 31, and aluminum in the liquid phase is diffused into silicon-germanium that forms the thermoelectric element 20 to isothermally solidify the bonded portion. Therefore, the bonding may be performed at 660° C. which is the melting point of aluminum or lower and the thermal stress occurring in the elements and the bonded portion at the time of cooling may be reduced. The alloy layer 302 is formed of silicon and germanium containing aluminum of 10 mass % or less and has a melting point higher than 660° C. which is the melting point of aluminum. Therefore, the alloy layer 302 has an excellent thermal resistance. The alloy layer 302 has silicon and germanium as main components and has a coefficient of thermal expansion equal to that of the thermoelectric element 20 formed of silicon-germanium and that of the molybdenum electrode 10, which may suppress the thermal stress of the elements and the bonded portion caused by the temperature difference at the time of driving the thermoelectric converting module 100.

In addition, since the intermediate layer 30 includes silicon and germanium that form the thermoelectric element 20, ohmic contact may occur between the thermoelectric element 20 and the molybdenum electrode and the contact resistance may be reduced to obtain excellent electric connection.

By the above-mentioned action, the intermediate layer 30 on which the alloy containing aluminum, silicon, and germanium is formed may exhibit high mechanical and electrical bonding reliability for a long time.

Further, the upper limit of the bonding temperature is a temperature that does not deteriorate the performance of the thermoelectric element and specifically 850° C. or lower.

In addition, in the above description, even though an aluminum foil is used as the metal foil, an aluminum alloy foil containing silicon and germanium in aluminum may be used instead of the aluminum foil. In this case, since aluminum contains a component of the thermoelectric element, the eutectic liquid phase may easily occur without going through the solid phase diffusion. Further, the aluminum foil and the aluminum alloy foil may be laminated.

Furthermore, instead of the metal foil, an aluminum powder or an aluminum alloy powder containing silicon and germanium in aluminum may be used. In this case, a single component powder may be used or layers formed of individual powders may be laminated or the mixture powder may be used. When the powder is used, it is preferable to use a beaten powder or a flattened powder, because both of the powers are easily disposed between the thermoelectric element and the electrode. When using the powder, a compact formed by compacting only the powder may be disposed between the thermoelectric element and the electrode or the powder may be casted at the end face of the electrode. Further, a powder pasted using a resin may be disposed so as to be applied at the end face of the thermoelectric element or a portion of the electrode which comes in contact with the thermoelectric element.

As a manufacturing method of the thermoelectric converting module illustrated in FIG. 2, for example, an electrode alignment jig (not illustrated) that may suck or adhere the electrode 10 and an element alignment jig (not illustrated) that may suck or adhere the thermoelectric element 20 are used to align the electrodes 10 and the thermoelectric elements 20 in a predetermined arrangement. Continuously, a metal foil 31 is provided on a lower electrode and a positioning jig is used to provide the thermoelectric element on the metal foil 31. Continuously, the positioning jig (not illustrated) is used to provide the metal foil 31 on the aligned thermoelectric elements. Thereafter, using a sucking and adhering alignment jig (not illustrated) and a positioning jig (not illustrated) are used to provide an upper electrode. A weight (not illustrated) is mounted on the upper electrode to perform pressurization, heating, and bonding by using a load of the weight.

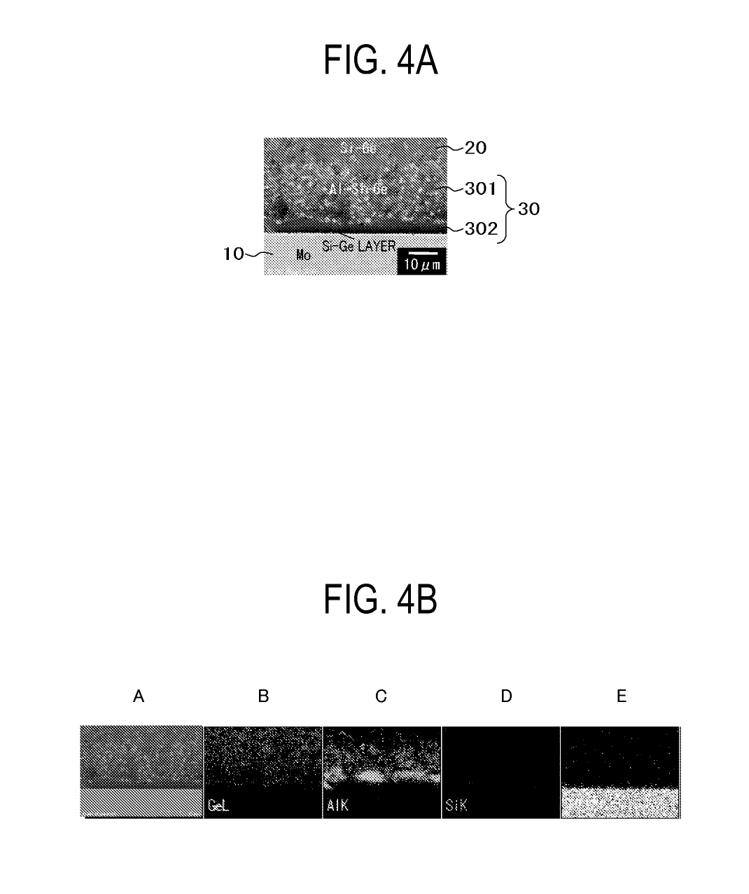

The thermoelectric converting module is manufactured as described above to obtain the intermediate layer 30 including an alloy layer including aluminum, silicon, and germanium and an alloy layer including silicon and germanium as main components and a small amount of aluminum. FIG. 4A illustrates an SEM image of a cross-section of the bonded portion when an aluminum foil having a thickness of 12.5 μm is provided as the metal foil 31 and (a) to (e) of FIG. 4B illustrate element mapping images by an EDX (energy dispersive X-ray spectroscopy) analyzing device. FIG. 4A illustrates an SEM image of the cross-section of the bonded portion. In FIG. 4B, (a) is a view illustrating a surface distribution for all elements, (b) is a view illustrating a surface distribution for germanium (Ge), (c) is a view illustrating a surface distribution for aluminum (Al), (d) is a view illustrating a surface distribution for silicon (Si), and (e) is a view illustrating a surface distribution for molybdenum (Mo). From the above result, it is understood that the intermediate layer 30 including two layers, that is, the alloy layer 301 containing silicon, germanium, and aluminum and the alloy layer 302 including silicon and germanium, and a small amount of aluminum of 10 mass % or less is formed from the side of the thermoelectric element 20 formed of silicon-germanium in the SEM image illustrated in FIG. 4A.

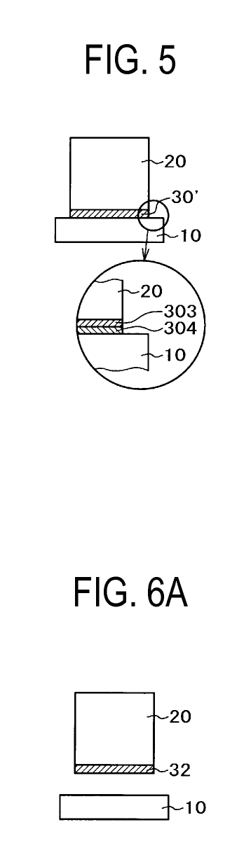

In the meantime, when the thickness of the aluminum foil 31 to be provided is 100 μm or larger, the volume of aluminum to be melted is large. Therefore, as schematically illustrated in FIG. 5, as an intermediate layer 30′, in the bonded portion, an alloy layer 303 containing silicon, germanium, and aluminum is provided at the side of the thermoelectric element 20 formed of silicon-germanium and an aluminum-rich alloy layer 304 including silicon of 10 mass % or less and germanium is formed at the side of the molybdenum electrode 10.

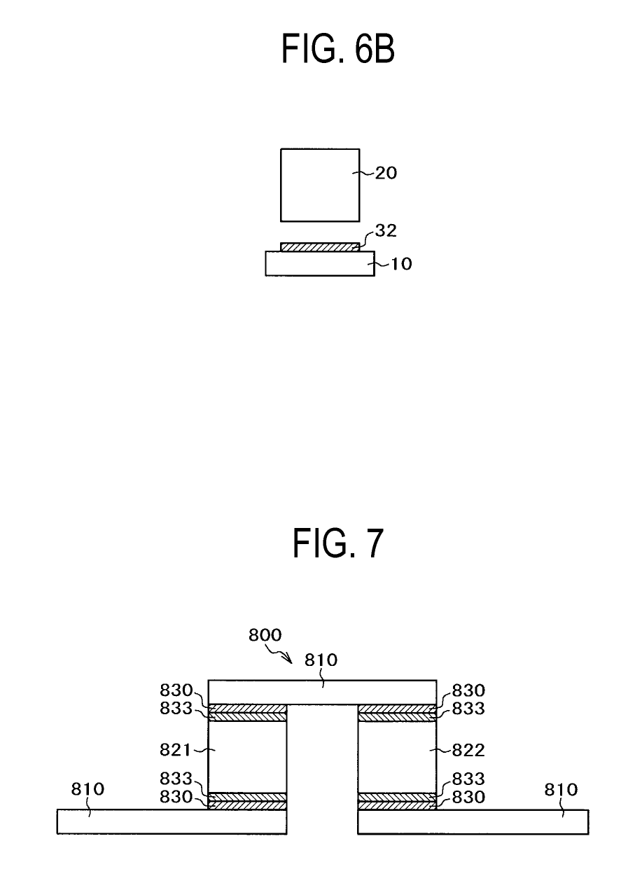

FIGS. 6A and 6B are schematic explanatory diagrams illustrating a manufacturing method when a metal layer 32 is provided instead of the metal foil 31 described in FIGS. 3A and 3C. In FIGS. 6A and 6B, reference numeral 10 denotes an electrode, reference numeral 20 denotes a thermoelectric element, and reference numeral 32 denotes a metal layer. The electrode 10 is a metal having molybdenum as a main component as described in FIGS. 3A to 3C and the thermoelectric element 20 is a semiconductor having silicon-germanium as a main component. The metal layer 32 is an aluminum layer formed on the thermoelectric element 20 or the electrode 10 using a film forming technology such as a deposition method, a sputtering method, a thermal spraying method, or an aerosol deposition method.

The aluminum layer may be formed on the thermoelectric element 20 as illustrated in FIG. 6A or at the side of the electrode 10 as illustrated in FIG. 6B using a film forming technology such as a deposition method, a sputtering method, a thermal spraying method, or an aerosol deposition method. As a manufacturing method of a thermoelectric converting module single body 1 illustrated in FIG. 2, similarly to the manufacturing method of the thermoelectric converting module single body 1 described with reference to FIGS. 3A to 3C, bonding is performed using an electrode alignment jig (not illustrated) that may suck or adhere the electrode 10 and an element alignment jig (not illustrated) that may suck or adhere the thermoelectric element 20. In this case, a process of providing a foil is omitted, which simplifies the manufacturing process.

According to the embodiment described above, there are various advantages and it is possible to implement a thermoelectric converting module having a bonding structure with a high bonding reliability.

Further, the intermediate layer 30 may be formed at both sides of the thermoelectric element 20. Further, when the intermediate layer is used as a thermoelectric converting module, the intermediate layer may be formed only between the electrode 10 which is disposed at a high temperature side and the thermoelectric element 20. In this case, an electrode which is disposed at a low temperature side may be bonded by a technology which has been performed in the related art such as a solder bonding, pressurizing, or compressed bonding.

Even though the thermoelectric element 20 is described using the silicon-germanium thermoelectric element as an example, different thermoelectric elements such as a magnesium silicide thermoelectric element and manganese silicide thermoelectric element may be used. In other words, these thermoelectric elements all contain silicon as a component and may be bonded by the aluminum and silicon liquid phase.

Here, when the magnesium silicide thermoelectric element is used as the thermoelectric element 20, the obtained intermediate layer 30 may have a layered structure having an alloy layer including silicon, magnesium, and aluminum and an alloy layer including silicon and magnesium as main components.

In order to obtain such an intermediate layer 30, instead of the aluminum foil 31 or the aluminum layer 32 in the above-mentioned manufacturing method, an aluminum alloy foil containing silicon and magnesium in aluminum or an aluminum alloy layer containing silicon and magnesium in aluminum may be used. Further, instead of the aluminum powder in the above-mentioned manufacturing method, an aluminum alloy powder containing silicon and magnesium in aluminum may be used.

However, in a case the magnesium silicide thermoelectric element is used as a thermoelectric element, since a eutectic liquid paste is generated between aluminum and magnesium at 437° C., a bonding temperature is set to 440° C. or higher. Further, magnesium may be easily vaporized at a high temperature, the upper limit of the bonding temperature is set to 800° C. in order to avoid the vaporization of magnesium. The other manufacturing conditions are the same with the silicon-germanium thermoelectric element as described above.

Further, when the manganese silicide thermoelectric element is used as the thermoelectric element 20, an intermediate layer 30 to be obtained may have a layered structure including an alloy layer including silicon, manganese, and aluminum and an alloy layer having silicon and manganese as main components.

In order to obtain the intermediate layer 30, instead of the aluminum foil 31 or the aluminum layer 32 in the above-described manufacturing method, an aluminum alloy foil containing silicon and manganese in aluminum or an aluminum alloy layer containing silicon and manganese in aluminum may be used. Further, instead of the aluminum powder in the above-mentioned manufacturing method, an aluminum alloy powder containing silicon and manganese in aluminum may be used.

When the magnesium silicide thermoelectric element is used as the thermoelectric element, the manufacturing conditions are the same with the silicon-germanium thermoelectric element as described above.

In the thermoelectric converting module according to the first embodiment, in order to form the intermediate layer 30, the bonding is performed using diffusion of component elements (silicon and germanium) from the thermoelectric element 20 and diffusion of aluminum into the thermoelectric element 20. By the heat generated at the time of driving the thermoelectric converting module, aluminum is further diffused into the thermoelectric element 20. With respect to the volume of the thermoelectric element 20 to be used, if the volume of the aluminum foil 31 is sufficiently small, the lowering of output or lowering of the converting efficiency may be insignificant. Specifically, a content percentage of aluminum is sufficiently smaller than a content percentage of impurities such as phosphorus included in the thermoelectric element 20, antimony, boron, gallium, or zinc, the lowering of output or lowering of the converting efficiency due to the diffusion of aluminum into the thermoelectric element 20 may be insignificant.

Further, the thermoelectric converting module according to a second embodiment of the present invention provides a barrier layer that prevents the diffusion of component elements from the thermoelectric element between the thermoelectric element and the intermediate layer in order to prevent the output of the thermoelectric element or the converting efficiency from being lowered.

FIG. 7 is a schematic cross-sectional view illustrating a thermoelectric converting module according to the second embodiment of the present invention. In FIG. 7, reference numeral 800 denotes a thermoelectric converting module, reference numeral 810 denotes an electrode, reference numeral 821 denotes an n type thermoelectric electrode, reference numeral 822 denotes a p type thermoelectric electrode, reference numeral 830 denotes an intermediate layer, and reference numeral 833 denotes a barrier layer.

The n type thermoelectric element 821 and the p type thermoelectric element 822 (hereinafter, collectively referred to as a thermoelectric element 820) that are used in the thermoelectric converting module according to the second embodiment may be a silicon-germanium thermoelectric element obtained by sintering silicon and germanium powders by a pulse discharging method or a hot press method, a magnesium silicide thermoelectric element obtained by sintering magnesium and silicon powders by a pulse discharging method or a hot press method, or a manganese silicide thermoelectric element obtained by sintering manganese and silicon powders by a pulse discharging method or a hot press method. In the second embodiment, the thermoelectric element 820 is described using the silicon-germanium thermoelectric element similarly to the first embodiment.

The electrode 810 which is used for the thermoelectric converting module according to the second embodiment may consist of at least molybdenum or a metal single body of copper, tungsten, titanium, or nickel or an alloy of metals including any one of copper, tungsten, titanium, and nickel or be configured by a of plural layers in which the single body of metals or the alloys thereof overlap each other. In the second embodiment, similarly to the first embodiment, the electrode 810 may be described using a molybdenum electrode.

The intermediate layer 830 formed by the thermoelectric converting module according to the second embodiment may be aluminum or an aluminum alloy layer that includes a component generating a liquid phase with aluminum. As the component that generates the liquid phase with aluminum, silicon, magnesium, or germanium may be exemplified. In the second embodiment, the intermediate layer 830 is described using an alloy layer including silicon and aluminum.

The barrier layer 833 formed in the second embodiment may be tungsten, titanium, chrome, nickel, palladium, or molybdenum.

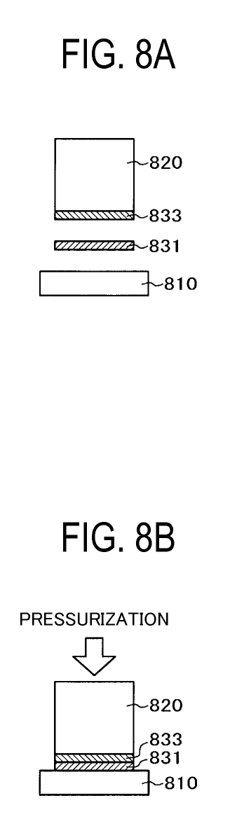

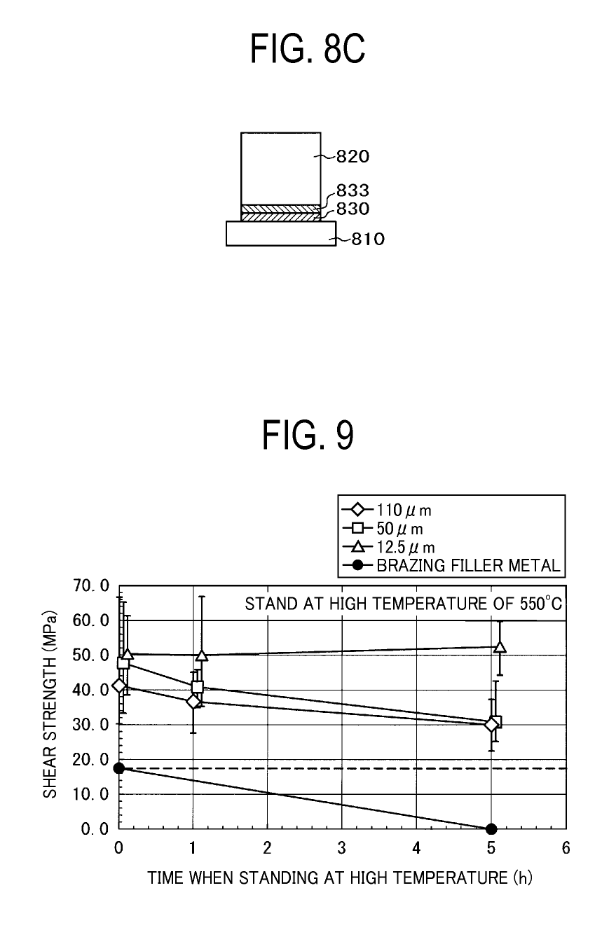

FIGS. 8A to 8C are schematic explanatory diagrams illustrating a manufacturing method of a thermoelectric converting module 800 according to the second embodiment illustrated in FIG. 7. In FIGS. 8A to 8C, reference numeral 810 denotes a molybdenum electrode, reference numeral 820 denotes a silicon-germanium thermoelectric element, reference numeral 830 denotes an intermediate layer including silicon and aluminum, reference numeral 831 denotes a metal foil, and reference numeral 833 denotes a barrier layer.

The metal foil 831 may be an aluminum foil, an aluminum alloy foil containing a eutectic liquid phase generating element such as silicon, an aluminum powder, or an aluminum alloy powder containing a eutectic liquid phase generating element such as silicon. Hereinafter, the metal foil 831 is described using an aluminum alloy foil containing silicon of 11.6 mass % in aluminum.

The barrier layer 833 is provided between the thermoelectric element 820 and the intermediate layer 830 in order to prevent the component of the thermoelectric element from being diffused from the thermoelectric element 820 onto the intermediate layer 830. The barrier layer 833 may be a metal layer including tungsten, titanium, nickel, palladium, or molybdenum or an alloy consisting of at least one of the above metals.

As illustrated in FIG. 8A, the barrier layer 833 is formed by metalizing on the surface of the silicon-germanium thermoelectric element by a deposition method, a sputtering method, a thermal spraying method, or an aerosol deposition method. The metal foil 831 which is an intermediate layer forming member is provided between the silicon-germanium thermoelectric element on which the barrier layer 833 is formed and the molybdenum electrode. Thereafter, as illustrated in FIG. 8B, while being pressurized from the upper portion of the silicon-germanium thermoelectric element with the same conditions as those described in the first embodiment, the thermoelectric converting module is heated at a temperature where the aluminum-silicon alloy provided as the metal foil 831 is melted. The bonding atmosphere may be a nonoxidation atmosphere such as a vacuum atmosphere, a nitrogen atmosphere, or a nitrogen and hydrogen mixture atmosphere.

Differently from the first embodiment, in the second embodiment, the barrier layer 833 prevents the diffusion of the component elements (silicon and germanium) of the thermoelectric element 820 from the thermoelectric element 820 onto the metal foil 831 which is an intermediate layer forming member and the diffusion of the component element (aluminum) of the metal foil 831 onto the thermoelectric element 820. However, since the metal foil 831 which is the intermediate layer forming member is formed of an aluminum alloy containing silicon in advance, similarly to the first embodiment, the metal foil 831 is melted at a eutectic liquid phase generating temperature (577° C.) of the aluminum and silicon. Thereafter, the metal foil 831 is cooled down to a room temperature to form the intermediate layer 830 containing aluminum and silicon between the silicon-germanium thermoelectric element on which the barrier layer 833 is formed and the molybdenum electrode as illustrated in FIG. 8C. The intermediate layer 830 has a high bonding strength and an excellent oxidation resistance in order to contain aluminum and silicon similarly to the first embodiment. Further, the bonded portion is hardly deteriorated even under a high temperature environment in the atmosphere. Furthermore, since the intermediate layer 30 contains silicon, the coefficient of thermal expansion of the intermediate layer 30 may approach the thermal expansion of the thermoelectric element 20 formed of silicon-germanium and the molybdenum electrode 10, and a thermal stress of the elements and the bonded portion caused by the temperature difference at the time of driving the thermoelectric converting module 100 may be reduced. By the effect of above, the intermediate layer 30 on which the alloy containing aluminum and silicon is formed may exhibit high bonding reliability for a long time.

As a manufacturing method of the thermoelectric converting module 800 illustrated in FIG. 7, similarly to the manufacturing method of the thermoelectric converting module according to the first embodiment, for example, an electrode alignment jig (not illustrated) that may suck or adhere the electrode 810, an element alignment jig (not illustrated) that may suck or adhere the thermoelectric element 820, and a positioning jig (not illustrated) are used to align and bond the electrodes 810 and the thermoelectric elements 820.

An aluminum alloy foil containing a eutectic liquid phase generating element such as silicon in aluminum is used as the metal foil 831, which may improve the bonding strength more than the solder material of the conventional art. Further, the barrier layer 833 is provided on the silicon-germanium thermoelectric element which is the thermoelectric element 820 to prevent the diffusion of the component of the metal foil 831 into the thermoelectric element 820 and increase the converting efficiency of the thermoelectric converting module.

In the thermoelectric converting module according to the second embodiment, an aluminum foil may be used as the metal foil 831 which is an intermediate layer forming member. In this case, the heating temperature may be higher than the melting point of aluminum and the intermediate layer 830 after cooled down is formed of aluminum. Since the intermediate layer 830 formed of aluminum is melted to be formed, the bonding strength is high, the oxidation resistance is excellent, and the bonded portion is hardly deteriorated even under a high temperature environment in the atmosphere. Furthermore, since the intermediate layer 830 contains silicon, the coefficient of thermal expansion of the intermediate layer 830 may approach the coefficient of the thermal expansion of the thermoelectric element 20 formed of silicon-germanium and the molybdenum electrode 10 and a thermal stress of the elements and the bonded portion caused by the temperature difference at the time of driving the thermoelectric converting module 100 is reduced. By the effect of above, the intermediate layer 30 formed of aluminum may exhibit high bonding reliability for a long time.

In the first embodiment, since the intermediate layer forming member is melted and diffuses the component elements of the thermoelectric element from the thermoelectric element onto the intermediate layer forming member, the thermoelectric element needs to contain silicon which generates a eutectic liquid paste with aluminum. In contrast, in the second embodiment, the barrier layer prevents the diffusion of the component elements of the thermoelectric element from the thermoelectric element onto the intermediate layer forming member. Therefore, the thermoelectric element is not limited to containing silicon but may use various thermoelectric elements which have been used in the conventional art.

### First Embodiment

As a thermoelectric element 20, a silicon-germanium thermoelectric element, a magnesium silicide thermoelectric element, and a manganese silicide thermoelectric element were prepared to be a quadrangular prism of 3.7 mm in length, 3.7 mm in width, and 4.0 mm in height. Further, as an electrode, a molybdenum electrode for the silicon-germanium thermoelectric element and a nickel electrode for the magnesium silicide thermoelectric element and the manganese silicide thermoelectric element were prepared to have a dimension of 4.5 mm in length, 10 mm in width, and 1.0 mm in thickness so as to be fitted with the size of the thermoelectric element 20. Further, as the metal foil, an aluminum foil having a thickness of Table 1 was prepared. As illustrated in FIG. 3A, the aluminum foil was provided between the silicon-germanium thermoelectric element and the molybdenum electrode, or the magnesium silicide thermoelectric element and the nickel electrode, or the manganese silicide thermoelectric element and the nickel electrode. Thereafter, as illustrated in FIG. 3B, while being pressurized from the upper portion of the thermoelectric element 20 with a pressure of Table 1, the thermoelectric converting module was heated at the atmosphere of Table 1 at a temperature and a holding time of Table 1 and then cooled to the room temperature to form a thermoelectric converting module with the intermediate layer 30 of FIG. 3C formed thereon.

In Table 1, results of bonding experiments of the thermoelectric converting modules are represented. With respect to the evaluation of the bonding status of Table 1, X indicates that a bonding interface is substantially not bonded, Δ indicates that a part of the bonding interface is not bonded, and ο indicates a good bonding status.

Sample numbers 01 to 03 of Table 1 indicate an influence of the bonding atmosphere which affects the bonding status when the silicon-germanium thermoelectric element and the molybdenum electrode are used. The bonding of the silicon-germanium thermoelectric element and the molybdenum electrode by the aluminum foil may achieve an excellent bonding status in any of vacuum atmosphere, nitrogen atmosphere, and nitrogen and hydrogen mixture atmosphere (referred to as “nitrogen+hydrogen”).

Sample numbers 04 to 07 of Table 1 indicate an influence of the holding temperature which affects the bonding status when the silicon-germanium thermoelectric element and the molybdenum electrode are used. In the bonding of the silicon-germanium thermoelectric element and the molybdenum electrode by the aluminum foil, the eutectic liquid paste of silicon and aluminum is not generated at the holding temperature of 550° C. of the sample number 07, which causes bad bonding. Therefore, the holding temperature is preferably a eutectic liquid paste generating temperature or higher. In the sample numbers 04 to 06 having a bonding temperature of 630° C. or higher, a non-bonded area is smaller and an excellent bonding status may be achieved.

TABLE 1

| | | Foil | Holding | Holding | | | |
|---|---|---|---|---|---|---|---|
| Sample | | thickness | temperature | time | | Pressure | Bonding |
| number | Element | (μm) | (° C.) | (sec) | Atmosphere | (kPa) | status |
| 01 | Si—Ge | 110 | 700 | 180 | Vacuum | 18.4 | ◯ |
| | | | | | (2.5 × 10⁻³ Pa) | | |
| 02 | Si—Ge | 110 | 700 | 180 | Nitrogen | 18.4 | ◯ |
| 03 | Si—Ge | 110 | 700 | 180 | Nitrogen | 18.4 | ◯ |
| | | | | | and | | |
| | | | | | hydrogen | | |
| | | | | | mixture | | |
| 04 | Si—Ge | 110 | 700 | 60 | Nitrogen | 18.4 | ◯ |
| 05 | Si—Ge | 110 | 680 | 60 | Nitrogen | 18.4 | ◯ |
| 06 | Si—Ge | 110 | 630 | 60 | Nitrogen | 18.4 | ◯ |
| 07 | Si—Ge | 110 | 550 | 60 | Nitrogen | 18.4 | X |
| 08 | Si—Ge | 110 | 680 | 60 | Nitrogen | 6.1 | ◯ |
| 09 | Si—Ge | 110 | 680 | 60 | Nitrogen | None | Δ |
| 10 | Si—Ge | 50 | 680 | 60 | Nitrogen | 6.1 | ◯ |
| 11 | Si—Ge | 25 | 680 | 60 | Nitrogen | 6.1 | ◯ |
| 12 | Si—Ge | 12.5 | 680 | 60 | Nitrogen | 6.1 | ◯ |
| 13 | Mg₂Si | 110 | 680 | 60 | Nitrogen | 6.1 | ◯ |
| 14 | Mg₂Si | 50 | 680 | 60 | Nitrogen | 6.1 | ◯ |
| 15 | Mg₂Si | 25 | 680 | 60 | Nitrogen | 6.1 | ◯ |
| 16 | Mg₂Si | 12.5 | 680 | 60 | Nitrogen | 6.1 | ◯ |
| 17 | MnSi | 110 | 680 | 60 | Nitrogen | 6.1 | ◯ |
| 18 | MnSi | 50 | 680 | 60 | Nitrogen | 6.1 | ◯ |
| 19 | MnSi | 25 | 680 | 60 | Nitrogen | 6.1 | ◯ |
| 20 | MnSi | 12.5 | 680 | 60 | Nitrogen | 6.1 | ◯ |

Sample numbers 05, 08, and 09 of Table 1 indicate an influence of the pressure which affects the bonding status when the silicon-germanium thermoelectric element and the molybdenum electrode are used. From the samples, a good bonding may be obtained in the pressure range of 6.1 to 18.4 kPa.

Sample numbers 08, 10, and 11 of Table 1 indicate an influence of the thickness of the aluminum foil which affects the bonding status when the silicon-germanium thermoelectric element and the molybdenum electrode are used. From the samples, a good bonding status may be obtained in any of the aluminum foil thickness of 12.5 to 110 μm. Further, in the sample number 11 in which a thickness of the aluminum foil is 12.5 μm, as an intermediate layer 30, an intermediate layer 30 formed of an alloy layer 301 containing silicon, germanium, and aluminum and an alloy layer 302 including silicon, germanium, and aluminum of 10 mass % or less is formed. In the sample in which a thickness of the aluminum foil is 110 μm, an intermediate layer 30′ formed of an alloy layer 303 containing silicon, germanium, and aluminum and an alloy layer 304 including an aluminum rich layer including silicon of 10 mass % or less and germanium is formed.

Sample numbers 13 to 16 of Table 1 indicate an influence of the thickness of the aluminum foil which affects the bonding status when the magnesium silicide thermoelectric element and the nickel electrode are used. From the samples, a good bonding status may be obtained in any of the aluminum foil thickness of 12.5 to 110 μm.

Sample numbers 17 to 20 of Table 1 indicate an influence of the thickness of the aluminum foil which affects the bonding status when the manganese silicide thermoelectric element and the nickel electrode are used. From the samples, a good bonding status may be obtained in any of the aluminum foil thickness of 12.5 to 110 μm.

FIG. 9 illustrates a graph representing a relationship between the holding time of the silicon-germanium at a high temperature and a shearing strength as a result of the bonding strength experiment of the first embodiment. In FIG. 9, indicates data when connecting is performed using the solder material of the conventional art.

Referring to FIG. 9, an initial bonding strength of the silicon-germanium thermoelectric element and the molybdenum electrode by the aluminum foil is twice higher than the strength when bonding is performed using the solder material of the conventional art and a high bonding reliability is ensured as compared to the conventional art. Further, when using the solder material of the conventional art, the bonding strength is not maintained after holding at a high temperature of 550° C. in the aerial atmosphere for five hours. In contrast, in the bonding of the silicon-germanium thermoelectric element and the molybdenum electrode by the aluminum foil, the strength is maintained to be higher than the initial bonding strength of the solder material of the conventional art even after holding at a high temperature of 550° C. in the aerial atmosphere for five hours and the thermal resistance is also excellent.

In the bonding of the silicon-germanium thermoelectric element and the molybdenum electrode by the aluminum foil, that the bonding is a metal bonding and the bonding strength is improved. Further, in the sample number 11 in which a thickness of the aluminum foil is 12.5 μm, even after holding an intermediate layer 30 formed of an alloy layer 301 containing silicon, germanium, and aluminum and an alloy layer 302 including silicon, germanium, and aluminum of 10 mass % or less at a high temperature, since the structure thereof is stable, the same strength as the initial bonding strength may be ensured.

Further, in case the thickness of the aluminum foil 31 is 50 μm or 110 μm, after holding at a high temperature of 550° C. in the aerial atmosphere for five hours, the diffusion is performed and the structure is changed in the aluminum rich layer. Therefore, the bonding strength is reduced by 20% of the initial strength. However, the bonding strength after five hours at 550° C. in the aerial atmosphere is higher than the initial bonding strength of the solder material of the conventional art. Therefore, it is possible to form a bonded portion having higher reliability in both of the aluminum foil thicknesses.

### Second Embodiment

The thermoelectric converting module single body 800 with the configuration illustrated in FIG. 7 was manufactured at the same condition as the first embodiment using the thermoelectric element 820 and the molybdenum electrode 810 which have the same shape as the first embodiment and pressured and overheated at the same conditions as the first embodiment represented in Table 1 to bond the thermoelectric element 820 and the molybdenum electrode 810.

As the result, the same result as the first embodiment represented in Table 1 was obtained.

As described above, according to the embodiments, a thermoelectric converting module having a bonding structure having various effects and a high bonding reliability may be implemented.

The invention may be embodied in other specific forms without departing from the spirit or essential characteristics thereof. The present embodiment is therefore to be considered in all respects as illustrative and not restrictive, the scope of the invention being indicated by the appended claims, rather than by the foregoing description, and all changes which come within the meaning and range of equivalency of the claims are therefore intended to be embraced therein.

1. A thermoelectric converting module, comprising:
a plurality of p type thermoelectric elements;
a plurality of n type thermoelectric elements;
a plurality of electrodes; and
a lead line,
wherein the plurality of p type thermoelectric elements, the plurality of n type thermoelectric elements, and the plurality of electrodes are electrically serially connected to each other, a pair of connecting lines that connects the lead line to one of the plurality of electrodes to output to the outside is further included, at least one electrode which is disposed at the high temperature side and the plurality of p type thermoelectric elements and the plurality of n type thermoelectric elements are bonded with an intermediate layer therebetween, and
wherein the plurality of p type thermoelectric elements and the plurality of n type thermoelectric elements contain silicon as a component and the intermediate layer is formed as a layer containing aluminum and silicon and components other than silicon of the thermoelectric elements.

2. The thermoelectric converting module according to claim 1, wherein at least one of the plurality of p type thermoelectric elements and the plurality of n type thermoelectric elements is formed of a silicon-germanium based thermoelectric element and the intermediate layer provided between the silicon-germanium based thermoelectric element and the electrode is formed as a layer containing aluminum or aluminum, silicon, and germanium.

3. The thermoelectric converting module according to claim 2, wherein the intermediate layer includes an alloy layer of aluminum and silicon containing germanium and an alloy layer having silicon and germanium as main components.

4. The thermoelectric converting module according to claim 2, wherein the intermediate layer includes an alloy layer of aluminum and silicon containing germanium and an alloy layer having aluminum as a main component.

5. The thermoelectric converting module according to claim 1, wherein at least one of the plurality of p type thermoelectric elements and the plurality of n type thermoelectric elements is formed of a magnesium silicide based thermoelectric element and the intermediate layer provided between the magnesium silicide based thermoelectric element and the electrode is formed as a layer containing aluminum or aluminum, silicon, and magnesium.

6. The thermoelectric converting module according to claim 5, wherein the intermediate layer includes an alloy layer of aluminum and silicon containing magnesium and an alloy layer having silicon and magnesium as main components.

7. The thermoelectric converting module according to claim 5, wherein the intermediate layer includes an alloy layer of aluminum and silicon containing magnesium and an alloy layer having aluminum as a main component.

8. The thermoelectric converting module according to claim 1, wherein at least one of the plurality of p type thermoelectric elements and the plurality of n type thermoelectric elements is formed of a manganese silicide based thermoelectric element and the intermediate layer provided between the manganese silicide based thermoelectric element and the electrode is formed as a layer containing aluminum or aluminum, silicon, and manganese.

9. The thermoelectric converting module according to claim 8, wherein the intermediate layer includes an alloy layer of aluminum and silicon containing manganese and an alloy layer having silicon and manganese as main components.

10. The thermoelectric converting module according to claim 8, wherein the intermediate layer includes an alloy layer of aluminum and silicon containing manganese and an alloy layer having aluminum as a main component.

11. A thermoelectric converting module, comprising:
a plurality of p type thermoelectric elements;
a plurality of n type thermoelectric elements;
a plurality of electrodes; and
a lead line,
wherein the plurality of p type thermoelectric elements, the plurality of n type thermoelectric elements, and the plurality of electrodes are electrically serially connected to each other, a pair of connecting lines that connects the lead line to one of the plurality of electrodes to output to the outside is further included, at least one electrode which is disposed at the high temperature side and the plurality of p type thermoelectric elements and the plurality of n type thermoelectric elements are bonded with an intermediate layer therebetween, and
wherein the plurality of p type thermoelectric elements and the plurality of n type thermoelectric elements contain silicon as a component, the plurality of p type thermoelectric elements and the plurality of n type thermoelectric elements are bonded to the intermediated with a barrier layer formed of tungsten, titanium, nickel, palladium, molybdenum or an alloy including any one of the above metals interposed therebetween, and the intermediate layer is formed as an aluminum layer or a layer containing aluminum and a component generating a liquid paste with aluminum.

12. A method of manufacturing a thermoelectric converting module, comprising the steps of:
providing p type thermoelectric elements and n type thermoelectric elements at a side of one surface of an electrode plate with an intermediate layer forming member interposed therebetween;
heating the p type thermoelectric elements and the n type thermoelectric elements while compressing the p type thermoelectric elements and the n type thermoelectric elements at a side of one surface of an electrode plate to melt the intermediate layer forming member; and
cooling the melted intermediate layer forming member to bond between the p type thermoelectric elements and the electrode plate and between the n type thermoelectric elements and the electrode plate,
wherein the p type thermoelectric elements and the n type thermoelectric elements contain silicon as a component, the intermediate layer forming member is formed of aluminum or an aluminum alloy containing a component of the thermoelectric elements containing the silicon as a component, and the heating is performed at a temperature where the intermediate layer forming member is melted.

13. The method of manufacturing a thermoelectric converting module according to claim 12, wherein as the p type thermoelectric elements and the n type thermoelectric elements, at least one of a silicon-germanium based thermoelectric element, a magnesium silicide based thermoelectric element, and a manganese silicide based thermoelectric element is used.

14. The method of manufacturing a thermoelectric converting module according to claim 12, wherein the intermediate layer forming member is at least one of an aluminum foil, an aluminum alloy foil containing at least the silicon in aluminum as a component, an aluminum powder, and an aluminum alloy powder containing at least the silicon in aluminum as a component.

15. A method of manufacturing a thermoelectric converting module, comprising the steps of:
providing both ends of p type thermoelectric elements and n type thermoelectric elements with an electrode plate interposed therebetween through an intermediate layer forming member;
heating the p type thermoelectric elements and the n type thermoelectric elements while compressing the p type thermoelectric elements and the n type thermoelectric elements at a side of one surface of an electrode plate to melt the intermediate layer forming member; and
cooling the melted intermediate layer forming member to bond between the p type thermoelectric elements and the electrode plate and between the n type thermoelectric elements and the electrode plate,
wherein the p type thermoelectric elements and the n type thermoelectric elements contain silicon as a component, the intermediate layer forming member is formed of aluminum or an aluminum alloy containing a component of the thermoelectric elements containing the silicon as a component, and the heating is performed at a temperature where the intermediate layer forming member is melted.

16. The method of manufacturing a thermoelectric converting module according to claim 15, wherein as the p type thermoelectric elements and the n type thermoelectric elements, at least one of a silicon-germanium based thermoelectric element, a magnesium silicide based thermoelectric element, and a manganese silicide based thermoelectric element is used.

17. The method of manufacturing a thermoelectric converting module according to claim 15, wherein the intermediate layer forming member is at least one of an aluminum foil, an aluminum alloy foil containing at least the silicon in aluminum as a component, an aluminum powder, and an aluminum alloy powder containing at least the silicon in aluminum as a component.

18. A method of manufacturing a thermoelectric converting module, comprising the steps of:
providing p type thermoelectric elements and n type thermoelectric elements at a side of one surface of an electrode plate with an intermediate layer forming member interposed therebetween;
heating the p type thermoelectric elements and the n type thermoelectric elements while compressing the p type thermoelectric elements and the n type thermoelectric elements at a side of one surface of the electrode plate to melt the intermediate layer forming member; and
cooling the melted intermediate layer forming member to bond between the p type thermoelectric elements and the electrode plate and between the n type thermoelectric elements and the electrode plate,
wherein the intermediate layer forming member is formed of aluminum or an aluminum alloy containing aluminum and a liquid phase generating component, a diffusion barrier layer is formed on end faces of the p type thermoelectric elements and the n type thermoelectric elements, the p type thermoelectric elements and the n type thermoelectric elements are provided so as to face the diffusion barrier layer and the intermediate layer forming member, and the heating is performed at a temperature where the intermediate layer forming member is melted.

19. The method of manufacturing a thermoelectric converting module according to claim 18, wherein the intermediate layer forming member is at least one of aluminum foil, aluminum alloy foil containing at least the silicon in aluminum as a component, aluminum powder, and aluminum alloy powder containing at least the silicon in aluminum as a component.

20. A method of manufacturing a thermoelectric converting module, comprising the steps of:
providing both one of p type thermoelectric elements and n type thermoelectric elements with an electrode plate interposed therebetween through an intermediate layer forming member;
heating the p type thermoelectric elements and the n type thermoelectric elements while compressing the p type thermoelectric elements and the n type thermoelectric elements at a side of one surface of an electrode plate to melt the intermediate layer forming member; and
cooling the melted intermediate layer forming member to bond between the p type thermoelectric elements and the electrode plate and between the n type thermoelectric elements and the electrode plate,
wherein the intermediate layer forming member is formed of aluminum or an aluminum alloy containing aluminum and a liquid paste generating component, a diffusion barrier layer is formed on end faces of the p type thermoelectric elements and the n type thermoelectric elements, the p type thermoelectric elements and the n type thermoelectric elements are provided so as to face the diffusion barrier layer and the intermediate layer forming member, and the heating is performed at a temperature where the intermediate layer forming member is melted.

21. The method of manufacturing a thermoelectric converting module according to claim 20, wherein the intermediate layer forming member is at least one of an aluminum foil, an aluminum alloy foil containing at least the silicon in aluminum as a component, an aluminum powder, and an aluminum alloy powder containing at least the silicon in aluminum as a component.
